(19) United States
(12) Patent Application Publication
(10) Pub. No.: US 2025/0385174 A1
(43) Pub. Date: Dec. 18, 2025

(54) CAPACITORS IN INTERCONNECT STRUCTURES OF INTEGRATED CIRCUITS

(71) Applicant: Taiwan Semiconductor Manufacturing Company, Ltd., Hsinchu (TW)

(72) Inventors: Ke-Jing YU, Kaohsiung City (TW); Anhao Cheng, Taichung City (TW); Yen-Liang Lin, Tainan City (TW); Ru-Shang Hsiao, Hsinchu (TW)

(73) Assignee: Taiwan Semiconductor Manufacturing Company, Ltd., Hsinchu (TW)

(21) Appl. No.: 18/976,483

(22) Filed: Dec. 11, 2024

Related U.S. Application Data
(60) Provisional application No. 63/659,398, filed on Jun. 13, 2024.

(51) Int. Cl. H01L 23/522; H01L 21/768; H10D 80/20

(52) U.S. Cl. CPC H01L 23/5223; H01L 21/76807; H01L 23/5226; H10D 80/215

(57) ABSTRACT

A semiconductor structure and a method of fabricating the structure are disclosed. The semiconductor structure includes a substrate, a device layer disposed on the substrate, a power line disposed on the device layer, a first capacitor circuit, a second capacitor circuit, and a control circuit disposed on the power line and configured to control the first capacitor circuit. The first capacitor circuit includes a first conductive via disposed on the power line, a first conductive line disposed on the first conductive via and aligned to a first side of the power line, and a first trench capacitor disposed on the first conductive line. The second capacitor circuit includes a second conductive via disposed on the power line, a second conductive line disposed on the second conductive via and aligned to a second side of the power line, and a second trench capacitor disposed on the second conductive line.

### CROSS-REFERENCE TO RELATED APPLICATIONS

This application claims the benefit of U.S. Provisional Patent Application No. 63/659,398, titled “MIM Capacitor Circuit with Common Power Rail,” filed Jun. 13, 2024, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs) and interconnect structures in integrated circuits (ICs). Such scaling down has increased the complexity of semiconductor manufacturing processes along with the complexity of routing metal lines of the interconnect structures.

### BRIEF DESCRIPTION OF THE DRAWINGS

Aspects of this disclosure are best understood from the following detailed description when read with the accompanying figures.

FIG. 1 illustrates a top-down view of an integrated circuit with trench capacitor circuits and control circuits, in accordance with some embodiments.

FIGS. 2-5 illustrate different cross-sectional views of an integrated circuit with trench capacitor circuits and control circuits, in accordance with some embodiments.

FIG. 6 illustrates a top-down view of another integrated circuit with trench capacitor circuits and control circuits, in accordance with some embodiments.

FIG. 7 illustrates a top-down view of another integrated circuit with trench capacitor circuits and control circuits, in accordance with some embodiments.

FIG. 8 illustrates a top-down view of another integrated circuit with trench capacitor circuits and control circuits, in accordance with some embodiments.

FIG. 9 illustrates a top-down view of another integrated circuit with trench capacitor circuits and control circuits, in accordance with some embodiments.

FIGS. 10 and 11 illustrate different cross-sectional views of another integrated circuit with trench capacitor circuits and control circuits, in accordance with some embodiments.

FIG. 12 is a flow diagram of a method for fabricating an integrated circuit with trench capacitor circuits and control circuits, in accordance with some embodiments.

FIGS. 13A-24A and 13B-24B illustrate cross-sectional views of an integrated circuit with trench capacitor circuits and control circuits at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The increasing demand for high-speed electronic devices has increased the demand for electronic devices with high storage capacity. As a result, there are continued efforts in the semiconductor industry to manufacture low-cost, high-performance, and high-storage integrated circuits (ICs). One of the approaches for achieving high-storage in ICs has been the integration of trench capacitor arrays in interconnect structures of the ICs. Increasing the density of trench capacitors per unit area in an IC can increase the IC's storage capacity. However, increasing the density of trench capacitors in the ICs to meet the ever-growing demand for higher storage capacity is challenging due to the limited narrow width (e.g., about 10 nm to about 30 nm) of the power lines in interconnect structures and the short lengths of metal lines (e.g., less than about 100 nm) that electrically connect the power lines to the trench capacitors. For example, due to these narrow power lines and short metal lines in interconnect structures, (i) each power line cannot be electrically connected to more than one column of trench capacitors in the trench capacitor array, (ii) the one column of trench capacitors can be arranged only along one side of the power line, (iii) each trench capacitor can be electrically connected to only an adjacent control circuit that is configured to control the trench capacitor, (iv) at least four power lines are placed in each trench capacitor unit cell in the ICs, which makes the scaling down of trench capacitor unit cells to meet the ever-growing demand for smaller ICs challenging, and (v) there are unused cell area between adjacent power lines in each trench capacitor unit cell, which also makes the scaling down of trench capacitor unit cells challenging.

To address the abovementioned challenges, the present disclosure provides example ICs with trench capacitor arrays in interconnect structures having improved features, such as: (i) smaller trench capacitor unit cells, (ii) increased density of trench capacitors per unit area of the ICs, (iii) flexible metal line routing between power lines and trench capacitors, and (iv) reduced resistance-capacitance (RC) delay in the ICs. The present disclosure also provides example methods of forming the example interconnect structures. In some embodiments, these improved features can be achieved by reducing the number of power lines in each trench capacitor unit cell and/or by increasing the width of the power lines (e.g., about 40 nm to about 80 μm). Reducing the number of power lines can reduce the size of the trench capacitor unit cells, while increasing the width of the power lines can increase the density of trench capacitors per unit area. With the use of wider power lines, the number of trench capacitors electrically connected to each power line can be increased because the wider power lines can provide increased flexibility in connecting the trench capacitors to the power lines. Due to the increased routing flexibility, in some embodiments, each power line can be electrically connected to two columns of trench capacitors, instead of only one column of trench capacitors. Also, due to the increased routing flexibility, the trench capacitors can be electrically connected to non-adjacent and adjacent control circuits by using longer metal lines (e.g., about 100 nm to about 1 μm long metal lines) and/or L-shaped metal lines.

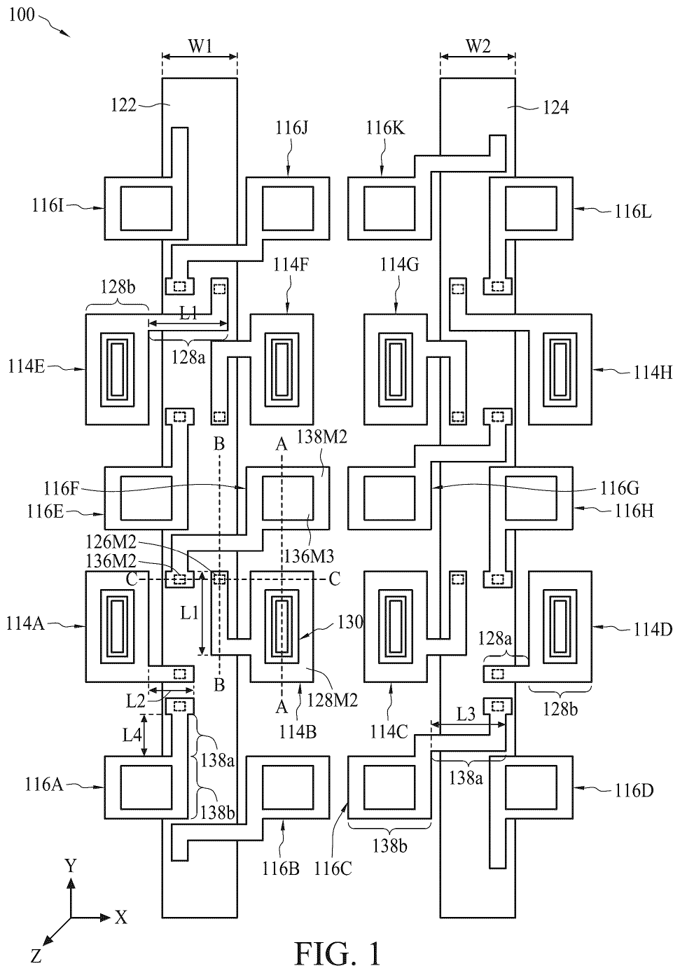

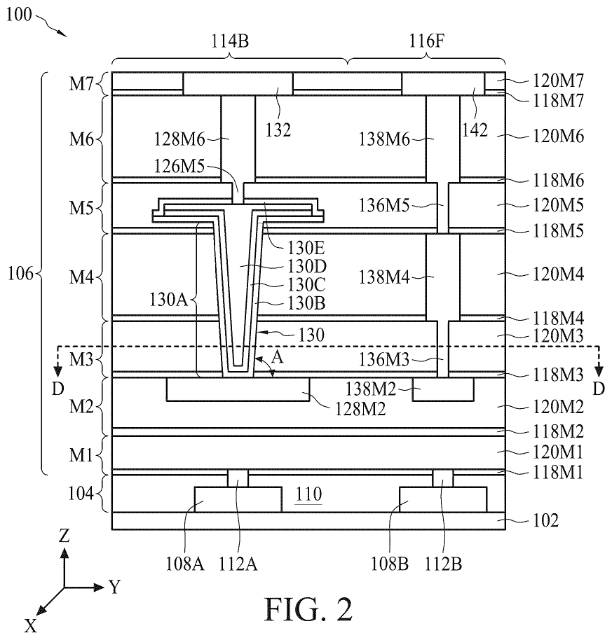

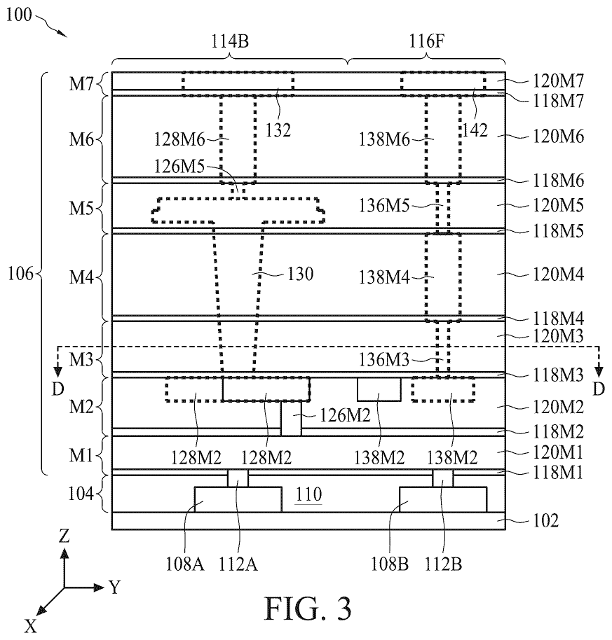

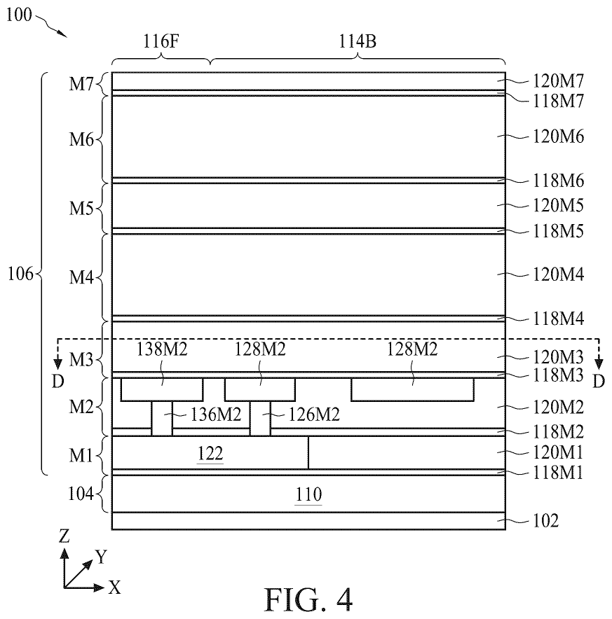

FIG. 1 illustrates a top-down view (also referred to as a “circuit layout”) of an IC 100, according to some embodiments. In some embodiments, the structure of FIG. 1 can represent a unit cell of IC 100. FIG. 2 illustrates a cross-sectional view of IC 100, along line A-A of FIG. 1, with additional structures that are not shown in FIG. 1 for simplicity, according to some embodiments. FIG. 3 illustrates a cross-sectional view of IC 100, along line B-B of FIG. 1, with additional structures that are not shown in FIG. 1 for simplicity, according to some embodiments. FIG. 4 illustrates a cross-sectional view of IC 100, along line C-C of FIG. 1, with additional structures that are not shown in FIG. 1 for simplicity, according to some embodiments. The top-down view of FIG. 1 can be along lines D-D of FIGS. 2, 3, and 4. The discussion of elements in FIGS. 1-4 with the same annotations applies to each other, unless mentioned otherwise.

Referring to FIGS. 1-4, IC 100 can include (i) a substrate 102, (ii) a device layer 104, and (iii) an interconnect structure 106. Substrate 102 and device layer 104 are not shown in FIG. 1 for simplicity. In some embodiments, substrate 102 can include a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic).

In some embodiments, device layer 104 can be disposed on substrate 102 and can include (i) FETs 108A and 108B, (ii) an interlayer dielectric (ILD) layer 110, and (iii) contact structures 112A and 112B. FETs 108A and 108B and contact structures 112A and 112B are not visible in the cross-sectional view of FIG. 4. In some embodiments, FETs 108A and 108B can be FinFETs, GAAFETs, or MOSFETs. In some embodiments, ILD layer 110 can be disposed on FETs 108A and 108B and can surround contact structures 112A and 112B. In some embodiments, ILD layer 110 can include a dielectric material, such as silicon oxide (SiO₂), silicon nitride (SiN), silicon oxynitride (SiON), silicon oxycarbide (SiOC), silicon carbon nitride (SiCN), and silicon oxycarbon nitride (SiOCN). In some embodiments, contact structure 112A can electrically connect FET 108A to interconnect structure 106 and contact structure 112B can electrically connect FET 108B to interconnect structure 106. In some embodiments, contact structures 112A and 112B can include a conductive material, such as cobalt (Co), tungsten (W), ruthenium (Ru), aluminum (Al), molybdenum (Mo), iridium (Ir), nickel (Ni), Osmium (Os), rhodium (Rh), other suitable conductive materials, and a combination thereof.

In some embodiments, interconnect structure 106 can include (i) interconnect layers M1-M7, (ii) an array of capacitor circuits 114A-114H, and (iii) an array of control circuits 116A-116L. In some embodiments, interconnect layer M1 can include (i) an etch stop layer (ESL) 118M1, (ii) an inter-metal dielectric (IMD) layer 120M1, (iii) a metal line 122, and (iv) a metal line 124. Metal line 122 is not visible in the cross-sectional view of FIG. 2 and metal line 124 is not visible in the cross-sectional views of FIGS. 2-4. In some embodiments, ESL 118M1 can include a dielectric carbide layer, such as SiC, SiCN, and other suitable dielectric carbide layers. Similarly, interconnect layers M2, M3, and M5 can include ESLs 118M2, 118M3, and 118M5, respectively, which can include materials similar to ESL 118M1. On the other hand, interconnect layers M4, M6, and M7 can include ESLs 118M4, 118M6, and 118M7, respectively, can include a dielectric material different from the dielectric material of ESLs 118M1, 118M2, 118M3, and 118M5. ESLs 118M4, 118M6, and 118M7 can include dielectric nitride layers, such as SiN, SiON, and other suitable dielectric nitride layers. In some embodiments, IMD layer 120M1 can include a low-k dielectric material, such as SiOC, SiCN, and SiOCN. Similarly, interconnect layers M2-M7 can include IMD layers 120M2-120M7, respectively, which can include materials similar to IMD layer 120M1. In some embodiments, interconnect layers M2-M7 can further include ESLs 118M2-118M7, respectively, which include materials similar to IMD layer 120M1. ESLs 118M1-118M3 and IMD layers 120M1-120M3 are not shown in FIG. 1 for simplicity.

In some embodiments, metal lines 122 and 124 can include Cu, W, Ru, or Al. Metal lines 122 and 124 can be disposed in IMD layer 120M1 and electrically connected to contact structures 112A and 112B through ESL 118M1. In some embodiments, metal lines 122 and 124 can be electrically connected to power supplies (e.g., Vdd and/or Vss; not shown), for which metal lines 122 and 124 can be referred to as “power lines 122 and 124” or “voltage supply lines 122 and 124.” As discussed above, in some embodiments, each unit cell of IC 100 can benefit from having two power lines 122 and 124, instead of four or more power lines because reducing the number of power lines can reduce the size of the unit cell of IC 100. In some embodiments, power lines 122 and 124 can be substantially parallel to each other and can have widths W1 and W2 of about 40 nm to about 80 μm. Such range of widths W1 and W2 can provide more flexible routing between power lines 122 and 124 and capacitor circuits 114A-114H and between power lines 122 and 124 and control circuits 116A-116L and reduce RC delay in IC 100 compared to power lines with widths less than W1 and W2. Due to the flexible routing, each of power lines 122 and 124 can be electrically connected to two columns of capacitor circuits from the array of capacitor circuits 114A-114H and two columns of control circuits from the array of control circuits 116A-116L, as shown in FIG. 1. As a result, the cell area between power lines 122 and 124 can be adequately utilized and the density of capacitor circuits can be increased compared to the density of capacitor circuits in ICs using four or more power lines in each unit cell and/or using power lines with widths less than W1 and W2.

Referring to FIG. 1, the rows in the array of capacitor circuits 114A-114H are arranged in an alternating configuration with the rows in the array of control circuits 116A-116L. Each of capacitor circuits 114A-114H can be controlled by a corresponding one of control circuits 116A-116L through one of power lines 122 and 124. For example, capacitor circuits 114A, 114B, 114E, and 114F can be electrically connected to and controlled by control circuits 116A, 116F, 116J, and 116E, respectively, through power line 122 and not electrically connected to any other control circuits. Similarly, capacitor circuits 114C, 114D, 114G, and 114H can be electrically connected to and controlled by control circuits 116H, 116C, 116G, and 116L, respectively, through power line 124 and not electrically connected to any other control circuits. In some embodiments, each of capacitor circuits 114A-114H can be further controlled by one or more FETs in device layer 104 (not visible in FIG. 1). Similarly, each of control circuits 116A-116L can be controlled by one or more FETs in device layer 104. For example, capacitor circuit 114B can be controlled by FET 108A and control circuit 116F can be controlled by FET 108B, as shown in FIGS. 2 and 3. Other FETs in device layer 104 for controlling capacitor circuits 114A and 114C-114H and control circuits 116A-116E and 116G-116L are not shown for simplicity.

Referring to FIGS. 1-4, each of capacitor circuits 114A-114H can include (i) a metal via 126M2 disposed in ESL 118M2 and IMD layer 120M2 of interconnect layer M2, (ii) a metal line 128M2 disposed in IMD layer 120M2 of interconnect layer M2, (iii) a trench capacitor 130, (iv) a metal via 126M5 disposed in trench capacitor 130 and IMD layer 120M5 of interconnect layer M5, (v) a metal line 128M6 disposed in ESL 118M6 and IMD layer 120M6 of interconnect layer M6, and (vi) a contact pad 132 disposed in ESL 118M7 and IMD layer 120M7 of interconnect layer M7. In some embodiments, metal vias 126M2 can be in direct contact with power line 122 or 124. Metal vias 126M5, metal lines 128M6, and contact pads 132 are not visible in the top-down view of FIG. 1. Though metal vias 126M2 can be underlying metal lines 128M2, as shown for capacitor circuit 114B in FIGS. 3 and 4, metal vias 126M2 are shown with dashed lines in FIG. 1 to illustrate relative positions of metal vias 126M2 with respect to metal lines 128M2 and power lines 122 and 124. The cross-sectional views of trench capacitors 130, metal vias 126M5, metal lines 128M6, and contact pads 132 of capacitor circuits 114A and 114C-114H along a YZ-plane can be similar to that of capacitor circuit 114B shown in FIG. 2. In some embodiments, depending on the layout configurations of metal vias 126M2 and metal lines 128M2 shown in FIG. 1, the cross-sectional views of metal vias 126M2 and metal lines 128M2 of capacitor circuits 114A and 114C-114H along YZ- and XZ-planes can be similar to or different from those of capacitor circuit 114B shown in FIGS. 3 and 4.

In some embodiments, each metal line 128M2 can include (i) a body portion 128b underlying trench capacitor 130, as shown in FIG. 1, and (ii) an arm portion 128a extending out from body portion 128b and overlying metal via 126M2 and power line 122 or 124, as shown in FIG. 1. In some embodiments, body portions 128b can have rectangular cross-sectional profiles along an XY-plane and can be non-overlapping with power lines 122 or 124 along an XY-plane. In some embodiments, each of body portions 128b can be aligned to one of the sides of power lines 122 or 124. For example, body portions 128b of capacitor circuits 114A and 114B can be aligned to either sides of power line 122 along a Y-axis and body portions 128b of capacitor circuits 114C and 114D can be aligned to either sides of power line 124 along a Y-axis. In some embodiments, the elongated sides of body portions 128b along a Y-axis can be substantially parallel to the elongated sides of power lines 122 and 124 along a Y-axis, as shown in FIG. 1. In some embodiments, arm portions 128a can have an L-shaped or an I-shaped cross-sectional profile along an XY-plane. For example, metal lines 128M2 of capacitor circuits 114B, 114C, and 114E-114H can have L-shaped arm portions 128a with lengths L1 of about 100 nm to about 1 μm and metal lines 128M2 of capacitor circuits 114A and 114D can have I-shaped arm portions 128a with lengths L2 of about 100 nm to about 1 μm.

The L-shaped and I-shaped arm portions 128a of metal lines 128M2 with such ranges of lengths L1 and L2 can be achieved due to the use of wider power lines 122 and 124 of widths W1 and W2, which provides increased routing flexibility between capacitor circuits and their corresponding control circuits. For example, with the use of L-shaped arm portion 128a of metal line 128M2, capacitor circuit 114C can be electrically connected to its control circuit 116H, which is not adjacent to capacitor circuit 114C. That is, capacitor circuit 114C and control circuit 116H can be positioned on either sides of power line 124, instead of the same side of power line 124. Similarly, capacitor circuits 114D, 114E, and 114F can be electrically connected to control circuits 116C, 116J, and 116E, respectively, which are not adjacent to capacitor circuits 114D, 114E, and 114F. Moreover, the L-shaped and I-shaped arm portions 128a of metal lines 128M2 can provide flexibility in electrically connecting capacitor circuits and their corresponding adjacent control circuits. For example, capacitor circuits 114A and 114B can be electrically connected to their control circuits 116A and 116F, respectively, which are adjacent to capacitor circuits 114A and 114B.

The discussion of capacitor circuit 114B below applies to capacitor circuits 114A and 114C-114H, unless mentioned otherwise. The cross-sectional view of capacitor circuit 114B in FIG. 2 is shown in dashed lines on the cross-sectional view of capacitor circuit 114B in FIG. 3 to illustrate the relative positions of power line 122, metal via 126M2, metal line 128M2, trench capacitor 130, metal via 126M5, metal line 128M6, and contact pad 132 with respect to each other. In some embodiments, metal vias 126M2 and 126M5 and metal lines 128M2 and 128M6 can include Cu, W, Ru, or Al. In some embodiments, contact pad 132 can include undoped Al or Cu-doped Al with a Cu concentration of about 3 atomic % to about 5 atomic %. In some embodiments, each pair of metal via 126M2 and metal line 128M2 and each pair of metal via 126M5 and metal line 128M6 of capacitor circuit 114B can be a dual damascene structure.

Trench capacitor 130 can be electrically connected to power line 122 and FET 108A through metal via 126M2 and metal line 128M2. In some embodiments, trench capacitor 130 can have a metal-insulator-metal (MIM) configuration and can be referred to as a MIM capacitor 130. In some embodiments, trench capacitor 130 can include (i) a trench 130A, (ii) a bottom conductive layer 130B, (iii) a high-k dielectric layer 130C, (iv) a top conductive layer 130D, and (v) a capping layer 130E. Bottom and top conductive layers 130B and 130D can form the parallel plates of trench capacitor 130, which are separated by high-k dielectric layer 130C. Bottom conductive layer 130B can be electrically connected to power line 122 and FET 108A through metal via 126M2 and metal line 128M2 to provide a first voltage V1 to bottom conductive layer 130B. Top conductive layer 130D can be electrically connected to contact pad 132 through metal via 126M5 and metal line 128M6 to provide a second voltage V2 to top conductive layer 130D that is higher or lower than first voltage V1.

In some embodiments, trench 130A can extend from interconnect layers M3 to M5 and can be disposed in ESL 118M3, IMD layer 120M3, ESL 118M4, IMD layer 120M4, ESL 118M5, and IMD layer 120M5. Trench 130A can have a height greater than about 500 nm (e.g., between about 500 nm and about 2 μm) and an aspect ratio greater than about 1:2 (e.g., between about 1:2 to about 1:4), where the aspect ratio is a ratio between the width and the height of trench 130A. In some embodiments, trench 130A can have a tapered structure with a sloped sidewall forming an angle A of about 85 degrees to about 89 degrees with a top surface of metal line 128M2.

Bottom conductive layer 130B can include (i) top horizontal portions, (ii) non-horizontal portions (also referred to as “sloped portions”), and (iii) a bottom horizontal portion. The top horizontal portions of bottom conductive layer 130B can be disposed in IMD layer 120M5. The non-horizontal portions of bottom conductive layer 130B can be disposed in trench 130A and in contact with sidewalls of ESL 118M3, IMD layer 120M3, ESL 118M4, IMD layer 120M4, ESL 118M5, and IMD layer 120M5. The bottom horizontal portion of bottom conductive layer 130B can be disposed in ESL 118M3 and can be disposed on and in contact with the top surface of metal line 128M2. In some embodiments, bottom conductive layer 130B can include a conductive material, such as titanium nitride (TiN), Al, Cu, and other suitable conductive materials.

High-k dielectric layer 130C can include (i) top horizontal portions, (ii) non-horizontal portions (also referred to as “sloped portions”), and (iii) a bottom horizontal portion. The top horizontal portions of high-k dielectric layer 130C can be disposed on and in contact with the top horizontal portions of bottom conductive layer 130B and can be disposed in IMD layer 120M5. The non-horizontal portions of high-k dielectric layer 130C can be disposed on and in contact with the non-horizontal portions of bottom conductive layer 130B and can extend through IMD layer 120M3, ESL 118M4, IMD layer 120M4, ESL 118M5, and IMD layer 120M5. The bottom horizontal portion of high-k dielectric layer 130C can be disposed on and in contact with the bottom horizontal portion of bottom conductive layer 130B and can be disposed in IMD layer 120M3. In some embodiments, high-k dielectric layer 130C can include a high-k dielectric material, such as hafnium oxide (HfOₓ), titanium oxide (TiO₂), hafnium zirconium oxide (HfZrO), tantalum oxide (Ta₂O₃), hafnium silicate (HfSiO₄), zirconium oxide (ZrOₓ), zirconium silicate (ZrSiO₂), aluminum oxide (AlOₓ), and other suitable high-k dielectric materials.

Top conductive layer 130D can include (i) a horizontal portion and (iii) a vertical portion. The horizontal portion of top conductive layer 130D can be disposed on and in contact with the top horizontal portions of high-k dielectric layer 130C and can be disposed in IMD layer 120M5. The vertical portion of top conductive layer 130D can be disposed on and in contact with the non-horizontal portions and the bottom horizontal portion of high-k dielectric layer 130C and can extend through IMD layer 120M3, ESL 118M4, IMD layer 120M4, ESL 118M5, and IMD layer 120M5. In some embodiments, the vertical portion of top conductive layer 130D can include a tapered structure with sloped sidewalls in contact with the non-horizontal portions of high-k dielectric layer 130C. In some embodiments, top conductive layer 130D can include a conductive material, such as tantalum nitride (TaN), Al, Cu, and other suitable conductive materials. In some embodiments, top and bottom conductive layers 130B and 130D can include the same or different conductive materials.

Capping layer 130E can include (i) bottom horizontal portions, (ii) vertical portions, and (iii) a top horizontal portion. The bottom horizontal portions of capping layer 130E can be disposed on and in contact with the top horizontal portions of bottom conductive layer 130B. The vertical portions of capping layer 130E can be disposed on and in contact with the sidewalls of the top horizontal portions of high-k dielectric layer 130C and the sidewalls of the horizontal portion of top conductive layer 130D. The top horizontal portion of capping layer 130E can be disposed on and in contact with the horizontal portion of top conductive layer 130D and can surround a bottom portion of metal via 126M5. In some embodiments, capping layer 130E can include a dielectric material, such as SiN, SiO₂, undoped silicate glass, or other suitable dielectric materials.

Referring to FIGS. 1-4, each of control circuits 116A-116L can include (i) a metal via 136M2 disposed in ESL 118M2 and IMD layer 120M2 interconnect layer M2, (ii) a metal line 138M2 disposed in IMD layer 120M2 of interconnect layer M2, (iii) a metal via 136M3 disposed in ESL 118M3 and IMD layer 120M3 of interconnect layer M3, (iv) a metal line 138M4 disposed in ESL 118M4 and IMD layer 120M4 of interconnect layer M4, (v) a metal via 136M5 disposed in ESL 118M5 and IMD layer 120M5 of interconnect layer M5, (vi) a metal line 138M6 disposed in ESL 118M6 and IMD layer 120M6 of interconnect layer M6, and (vii) a contact pad 142 disposed in ESL 118M7 and IMD layer 120M7 of interconnect layer M7. In some embodiments, metal vias 136M2 can be in direct contact with power line 122 or 124. Metal via 136M5, metal lines 138M4 and 138M6, and contact pads 142 are not visible in the top-down view of FIG. 1. Though metal vias 136M2 can be underlying metal lines 138M2, as shown for control circuit 116F in FIG. 4, metal vias 136M2 are shown with dashed lines in FIG. 1 to illustrate relative positions of metal vias 136M2 with respect to metal lines 138M2 and power lines 122 and 124. The cross-sectional views of metal vias 136M3 and 136M5, metal lines 138M4 and 138M6, and contact pads 142 of control circuits 116A-116E and 116G-116L along a YZ-plane can be similar to that of control circuit 116F shown in FIG. 2. In some embodiments, depending on the layout configurations of metal vias 136M2 and metal lines 138M2 shown in FIG. 1, the cross-sectional views of metal vias 136M2 and metal lines 138M2 of control circuits 116A-116E and 116G-116L along YZ- and XZ-planes can be similar to or different from those of control circuit 116F shown in FIGS. 3 and 4.

In some embodiments, each metal line 138M2 can include (i) a body portion 138b underlying metal via 136M3, as shown in FIG. 1, and (ii) an arm portion 138a extending out from body portion 138b and overlying metal via 136M2 and power line 122 or 124, as shown in FIG. 1. In some embodiments, body portions 138b can have rectangular cross-sectional profiles along an XY-plane and can be non-overlapping or partially overlapping with power lines 122 or 124 along an XY-plane. In some embodiments, arm portions 138a can have an L-shaped or an I-shaped cross-sectional profile along an XY-plane. For example, metal lines 138M2 of control circuits 116B, 116C, 116F, 116G, 116J, and 116K can have L-shaped arm portions 138a with lengths L3 of about 100 nm to about 1 μm and metal lines 138M2 of control circuits 116A, 116D, 116E, 116H, 116I, and 116L can have I-shaped arm portions 138a with lengths L4 of about 100 nm to about 1 μm. Similar to arm portions 128a of metal lines 128M2, the L-shaped and I-shaped arm portions 138a of metal lines 128M2 with such ranges of lengths L3 and L4 can be achieved due to the use of wider power lines 122 and 124, which provides increased routing flexibility between capacitor circuits and their corresponding adjacent or non-adjacent control circuits.

The discussion of control circuit 116F below applies to control circuits 116A-116E and 116G-116L, unless mentioned otherwise. The cross-sectional view of control circuit 116F in FIG. 2 is shown in dashed lines on the cross-sectional view of control circuit 116F in FIG. 3 to illustrate the relative positions of power line 122, metal via 126M2, 126M5, 136M2, 136M3, and 136M5, metal lines 128M2, 128M6, 138M2, 138M4, and 138M6, trench capacitor 130, and contact pads 132 and 142 with respect to each other. In some embodiments, metal vias 136M2, 136M3, and 136M5 and metal lines 138M2, 138M4, and 138M6 can include Cu, W, Ru, or Al. In some embodiments, metal vias 136M2 and 136M5 can have the same material as metal vias 126M2 and 126M5, respectively, and metal lines 138M2 and 138M6 can have the same material as metal lines 128M2 and 128M6, respectively. In some embodiments, contact pad 142 can have the same material as contact pad 132. In some embodiments, each pair of (i) metal via 136M2 and metal line 138M2, (ii) metal via 136M3 and metal line 138M4, and (iii) metal via 136M5 and metal line 138M6 of control circuit 116F can be a dual damascene structure. In some embodiments, an input signal can be received by contact pad 142 of control circuit 116F and can be sent to FET 108B through metal via 136M2, 136M3, and 136M5, metal lines 138M2, 138M4, and 138M6, and contact structure 112B. Based on the input signal, trench capacitor 130 of capacitor circuit 114B can be controlled and an output signal can be obtained from contact pad 132 of capacitor circuit 114B. In some embodiments, other interconnect layers and/or devices can be present over interconnect layer M7, which are not shown for simplicity.

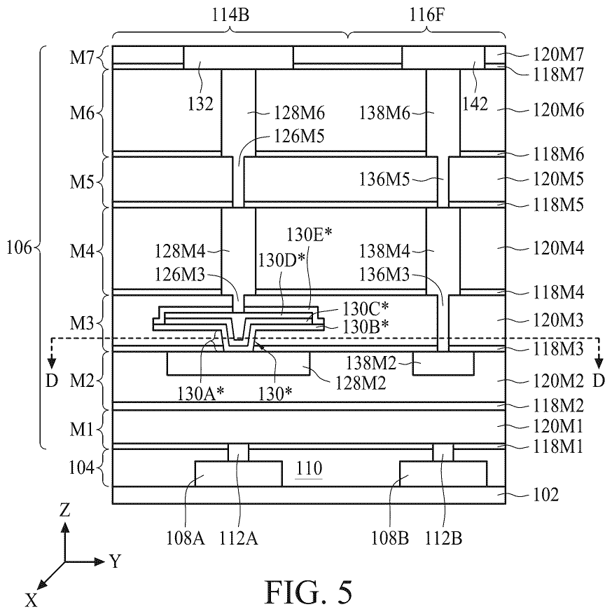

In some embodiments, instead of the cross-sectional view of FIG. 2, IC 100 can have the cross-sectional view of FIG. 5 along line A-A of FIG. 1, with additional structures that are not shown in FIG. 1 for simplicity. The top-down view of FIG. 1 can be along lines D-D of FIG. 5. The discussion of capacitor circuit 114B in FIG. 5 applies to capacitor circuits 114A and 114C-114H, unless mentioned otherwise. The discussion of elements in FIGS. 1-5 with the same annotations applies to each other, unless mentioned otherwise.

Referring to FIG. 5, in some embodiments, capacitor circuit 114B can include (i) metal via 126M2 (not visible in cross-sectional view of FIG. 5) disposed in ESL 118M2 and IMD layer 120M2 of interconnect layer M2, (ii) metal line 128M2 disposed in IMD layer 120M2 of interconnect layer M2, (iii) a trench capacitor 130*, instead of trench capacitor 130 of FIG. 2, (iv) a metal via 126M3 disposed in trench capacitor 130* and IMD layer 120M3 of interconnect layer M3, (v) a metal line 128M4 disposed in ESL 118M4 and IMD layer 120M4 of interconnect layer M4, (vi) metal via 126M5 disposed in ESL 118M5 and IMD layer 120M2 of interconnect layer M5, (vii) metal line 128M6 disposed in ESL 118M6 and IMD layer 120M6 of interconnect layer M6, and (viii) contact pad 132 disposed in ESL 118M7 and IMD layer 120M7 of interconnect layer M7. In some embodiments, metal via 126M3 and metal line 128M4 can have the same material as metal via 136M3 and metal line 138M4, respectively. Metal via 126M3 and metal line 128M4 can be a dual damascene structure.

The discussion of trench capacitor 130 applies to trench capacitor 130*, unless mentioned otherwise. In some embodiments, trench capacitor 130* can include (i) a trench 130A*, (ii) a bottom conductive layer 130B*, (iii) a high-k dielectric layer 130C*, (iv) a top conductive layer 130D*, and (v) a capping layer 130E*. The discussion of trench 130A, bottom conductive layer 130B, high-k dielectric layer 130C, top conductive layer 130D, and capping layer 130E applies to trench 130A*, bottom conductive layer 130B*, high-k dielectric layer 130C*, top conductive layer 130D*, and capping layer 130E*, respectively, unless mentioned otherwise.

In some embodiments, trench 130A* can be disposed in ESL 118M3 and IMD layer 120M of interconnect layer M3 and can have a tapered structure with sloped sidewalls. Bottom conductive layer 130B* can include (i) top horizontal portions, (ii) non-horizontal portions, and (iii) a bottom horizontal portion. The top horizontal portions of bottom conductive layer 130B* can be disposed in IMD layer 120M3. The non-horizontal portions of bottom conductive layer 130B* can be disposed in trench 130A* and in contact with sidewalls of ESL 118M3 and IMD layer 120M3. The bottom horizontal portion of bottom conductive layer 130B* can be disposed in ESL 118M3 and can be disposed on and in contact with the top surface of metal line 128M2.

High-k dielectric layer 130C* can include (i) top horizontal portions disposed in IMD layer 120M3, (ii) non-horizontal portions disposed in IMD layer 120M3, and (iii) a bottom horizontal portion disposed in IMD layer 120M3. Top conductive layer 130D* can include (i) a horizontal portion disposed in IMD layer 120M3 and (iii) a vertical portion disposed in IMD layer 120M3. Capping layer 130E* can include (i) bottom horizontal portions disposed in IMD layer 120M3, (ii) vertical portions disposed in IMD layer 120M3, and (iii) a top horizontal portion disposed in IMD layer 120M3. The top horizontal portion of capping layer 130E* can surround a bottom portion of metal via 126M3.

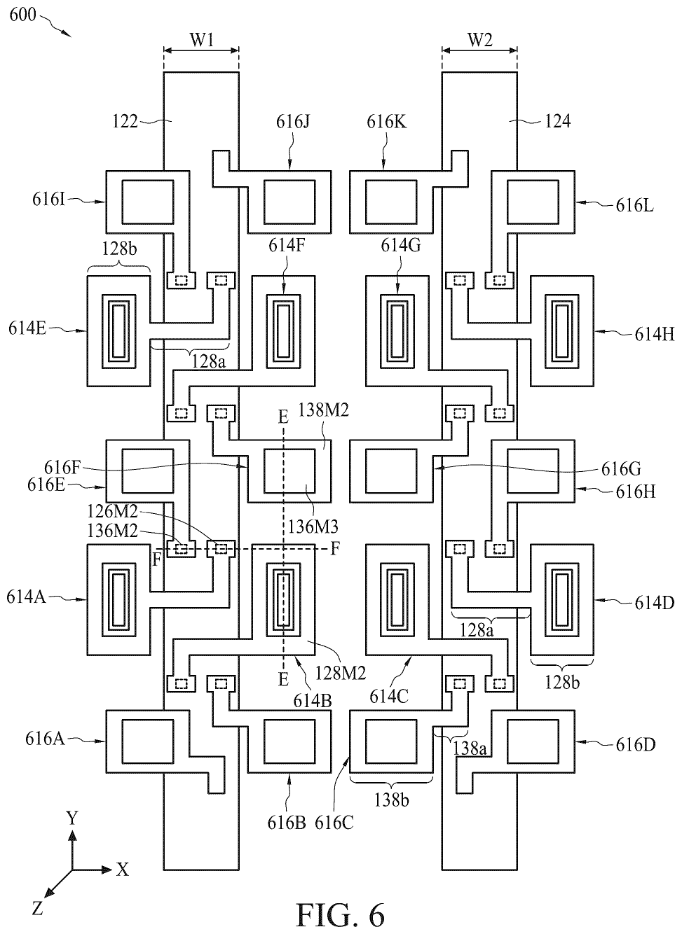

FIG. 6 illustrates a top-down view of an IC 600, according to some embodiments. In some embodiments, the structure of FIG. 6 can represent a unit cell of IC 600. The discussion of IC 100 applies to IC 600, unless mentioned otherwise. IC 600 can have the cross-sectional view of FIG. 2 or FIG. 5 along line E-E, according to some embodiments. IC 600 can have the cross-sectional view of FIG. 4 along line F-F, according to some embodiments. The discussion of elements in FIGS. 1-6 with the same annotations applies to each other, unless mentioned otherwise.

In some embodiments, similar to IC 100, IC 600 can include substrate 102, device layer 104, and interconnect layers M1-M7. IC 600 can further include an array of capacitor circuits 614A-614H and an array of control circuits 616A-616L in interconnect layers M1-M7. The discussion of capacitor circuits 114A-114H applies to the discussion of capacitor circuits 614A-614H, respectively, except the layout of metal vias 126M2 and metal lines 128M2 (shown in FIG. 6) of capacitor circuits 614A-614H are different from the layout of metal vias 126M2 and metal lines 128M2 (shown in FIG. 1) of capacitor circuits 114A-114H. Similarly, the discussion of control circuits 116A-116L applies to the discussion of control circuits 616A-616L, respectively, except the layout of metal vias 136M2 and metal lines 138M2 (shown in FIG. 6) of control circuits 616A-616L are different from the layout of metal vias 136M2 and metal lines 138M2 (shown in FIG. 1) of control circuits 116A-116L. Unlike IC 100, metal vias 126M2 and metal lines 128M2 of capacitor circuits 614A-614H and metal vias 136M2 and metal lines 138M2 of control circuits 616A-616L are arranged to electrically connect each capacitor circuit to its corresponding adjacent control circuit and not to electrically connect to any non-adjacent control circuits. For example, capacitor circuits 614A, 614B, 614C, and 614D are electrically connected to their adjacent control circuits 616E, 616B, 616C, and 616H, respectively.

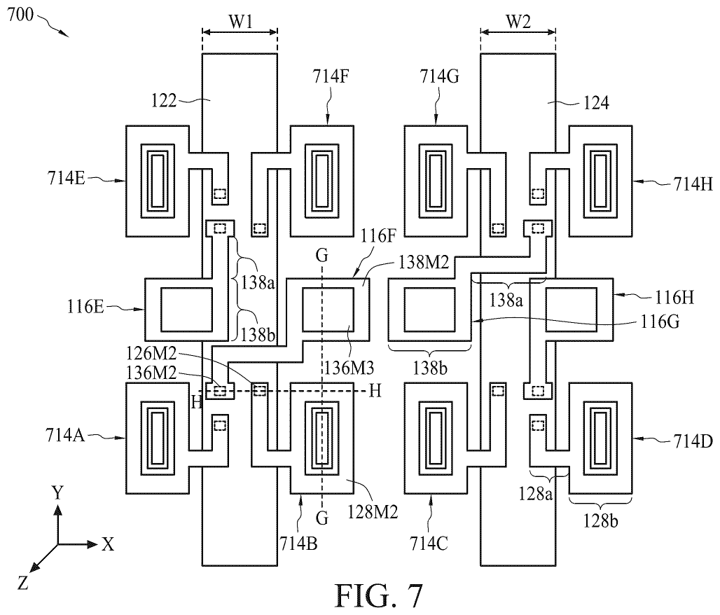

FIG. 7 illustrates a top-down view of an IC 700, according to some embodiments. In some embodiments, the structure of FIG. 7 can represent a unit cell of IC 700. The discussion of IC 100 applies to IC 700, unless mentioned otherwise. IC 700 can have the cross-sectional view of FIG. 2 or FIG. 5 along line G-G, according to some embodiments. IC 700 can have the cross-sectional view of FIG. 4 along line H-H, according to some embodiments. The discussion of elements in FIGS. 1-7 with the same annotations applies to each other, unless mentioned otherwise.

In some embodiments, similar to IC 100, IC 700 can include substrate 102, device layer 104, and interconnect layers M1-M7. IC 700 can further include an array of capacitor circuits 714A-714H and an array of control circuits 116E-116E in interconnect layers M1-M7. The discussion of capacitor circuits 114A-114H applies to the discussion of capacitor circuits 714A-714H, respectively, except the layout of metal vias 126M2 and metal lines 128M2 (shown in FIG. 7) of capacitor circuits 714A-714H are different from the layout of metal vias 126M2 and metal lines 128M2 (shown in FIG. 1) of capacitor circuits 114A-114H. Unlike IC 100, metal vias 126M2 and metal lines 128M2 of capacitor circuits 714A-714H are arranged to electrically connect two capacitor circuits to each control circuit. That is, two capacitor circuits can be controlled by one control circuit. For example, capacitor circuits 714A and 714B can be electrically connected to and controlled by control circuit 116F, capacitor circuits 714C and 714D can be electrically connected to and controlled by control circuit 116H, capacitor circuits 714E and 714F can be electrically connected to and controlled by control circuit 116E, and capacitor circuits 714G and 714H can be electrically connected to and controlled by control circuit 116G.

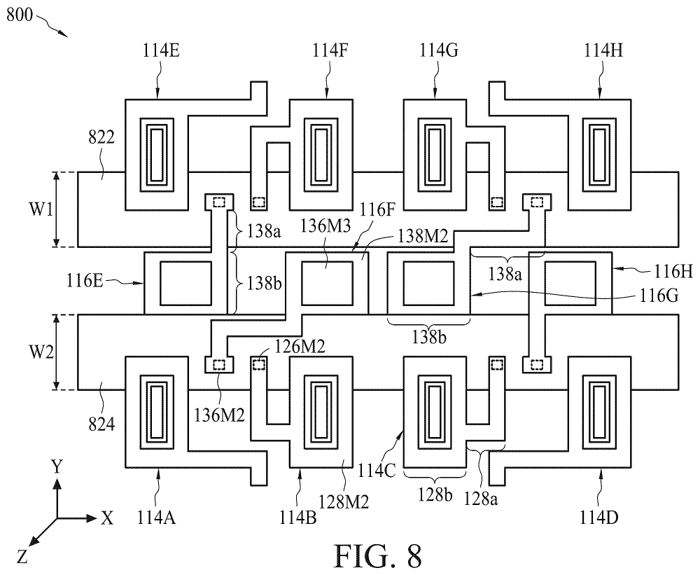

FIG. 8 illustrates a top-down view of an IC 800, according to some embodiments. In some embodiments, the structure of FIG. 8 can represent a unit cell of IC 800. The discussion of IC 100 applies to IC 800, unless mentioned otherwise. The discussion of elements in FIGS. 1-8 with the same annotations applies to each other, unless mentioned otherwise.

In some embodiments, similar to IC 100, IC 800 can include substrate 102, device layer 104, interconnect layers M1-M7, an array of capacitor circuits 114A-114H, and an array of control circuits 116E-116H. IC 800 can further include power lines 822 and 824 disposed in interconnect line M1. The discussion of power lines 122 and 124 applies to power lines 822 and 824, respectively, except the layout of power lines 822 and 824 are different from the layout of power lines 122 and 124. Unlike power lines 122 and 124, power lines 822 and 824 can be arranged to have their elongated sides along an X-axis substantially perpendicular to the elongated sides of body portions 128b of metal lines 128M2 along a Y-axis. Furthermore, body portions 128b can be partially overlapping with power lines 822 and 824 along an XY-plane. In some embodiments, the different layouts of FIG. 6-8 can be different portions of IC 100, instead of different ICs.

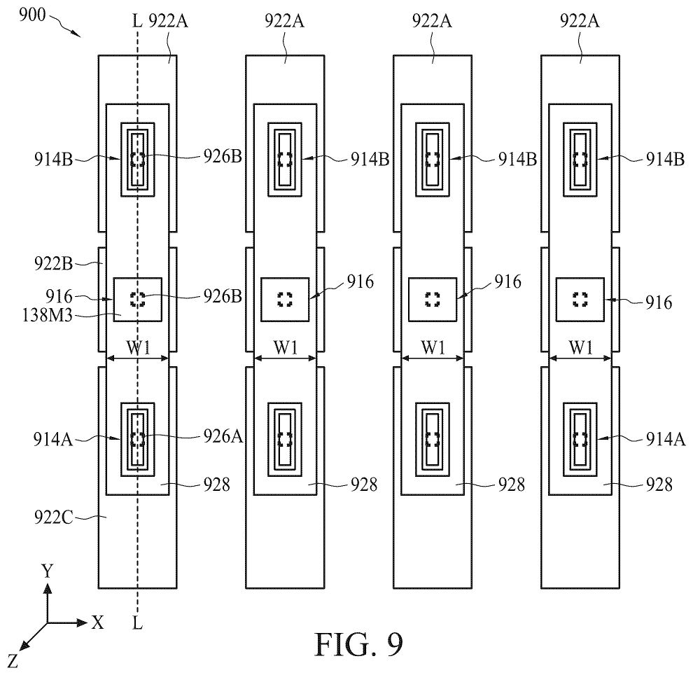

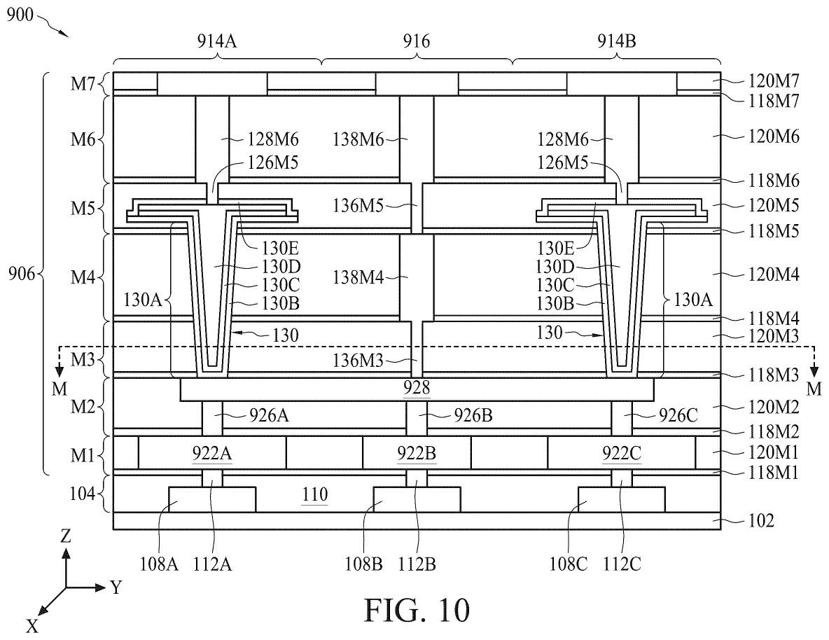

FIG. 9 illustrates a top-down view of an IC 900, according to some embodiments. In some embodiments, the structure of FIG. 9 can represent a unit cell of IC 900. FIG. 10 illustrates a cross-sectional view of IC 900, along line L-L of FIG. 9, with additional structures that are not shown in FIG. 9 for simplicity, according to some embodiments. The top-down view of FIG. 9 can be along lines M-M of FIG. 10. The discussion of elements in FIGS. 1-10 with the same annotations applies to each other, unless mentioned otherwise.

Referring to FIGS. 9 and 10, IC 900 can include (i) substrate 102, (ii) device layer 104, and (iii) an interconnect structure 906. In some embodiments, device layer 104 can include (i) FETs 108A-108C, (ii) ILD layer 110, and (iii) contact structures 112A-112C. In some embodiments, FETs 108A-108C can be FinFETs, GAAFETs, or MOSFETs. In some embodiments, contact structures 112A-112C can electrically connect FETs 108A-108C to interconnect structure 906. Contact structure 112C can include the same material as contact structures 112A and 112B.

In some embodiments, interconnect structure 906 can include (i) interconnect layers M1-M7, (ii) an array of capacitor circuits 914A, (iii) an array of capacitor circuits 914B, and (iii) an array of control circuits 916. In some embodiments, interconnect layer M1 can include (i) ESL 118M1, (ii) IMD layer 120M1, (iii) an array of metal lines 922A, (iv) an array of metal lines 922B, and (v) an array of metal lines 922C. ESLs 118M1-118M3 and IMD layers 120M1-120M3 of interconnect layers M1-M3 are not shown in FIG. 9 for simplicity. In some embodiments, interconnect layer M2 can include (i) ESL 118M2, (ii) IMD layer 120M2, (iii) an array of metal vias 926A, (iv) an array of metal vias 926B, (v) an array of metal vias 926C, and (vi) metal lines 928. Though metal vias 926A-926C can be underlying metal lines 928, as shown in FIG. 10, metal vias 926A-926C are shown with dashed lines in FIG. 9 to illustrate relative positions of metal vias 926A-926C with respect to metal lines 928, capacitor circuits 914A and 914B, and control circuits 916. In some embodiments, metal lines 922A-922C, 926A-9236C, and 928 can include Cu, W, Ru, or Al. Metal vias 926A-926C can be disposed directly on metal lines 922A-922C, respectively, and can be disposed in ESL 118M2 and IMD layer 120M2.

Metal lines 928 can be disposed in IMD layer 120M2 and electrically connected to metal vias 926A-926C. In some embodiments, metal lines 928 can be electrically connected to power supplies (e.g., Vdd and/or Vss; not shown), for which metal lines 928 can be referred to as “power lines 928.” Each power rail 928 can be electrically connected to and underlying a pair of capacitor circuits 914A and 914B and a control circuit 916 disposed between the pair of capacitor circuits 914A and 914B. As a result, each power rail 928 can act as a common power rail to a pair of capacitor circuits 914A and 914B and a control circuit 916, which controls the pair of capacitor circuits 914A and 914B. With such layout of power rails 928 with respect to capacitor circuits 914A and 914B and control circuits 916, extended arm portions of metal lines are not used to electrically connect power lines 928 to capacitor circuits 914A and 914B and control circuits 916, as discussed above with reference to FIG. 1. Thus, such layout of power rails 928 can further increase the density of capacitor circuits, while reducing or minimizing the size of the unit cell of IC 900.

In some embodiments, capacitor circuits 914A and 914B can be further controlled by FETs 108A and 108C, respectively. Similarly, each of control circuits 916 can be controlled by FET 108B. Each of capacitor circuits 914A and 914B can include (i) trench capacitor 130, (ii) metal via 126M5, (iii) metal line 128M6, and (iv) contact pad 132. Trench capacitors 130 can be directly connected to power line 928. The bottom horizontal portions of bottom conductive layers 130B of trench capacitors 130 can be disposed in ESL 118M3 and can be disposed on and in contact with the top surface of power lines 928. Each of control circuits 916 can include (i) metal via 136M3, (ii) metal line 138M4, (iii) metal via 136M5, (iv) metal line 138M6, and (v) contact pad 142. In some embodiments, metal vias 136M3 can be in direct contact with power lines 928. In some embodiments, an input signal can be received by contact pad 142 of control circuit 916 and can be sent to FET 922B. Based on the input signal, trench capacitors 130 of capacitor circuits 914A and 914B can be controlled and an output signal can be obtained from contact pads 132 of capacitor circuits 914A and 914B.

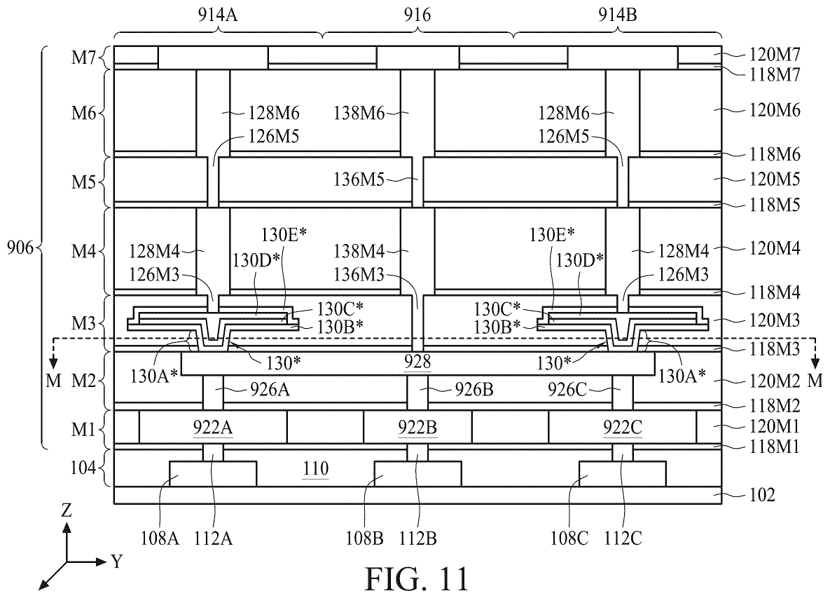

In some embodiments, instead of the cross-sectional view of FIG. 10, IC 900 can have the cross-sectional view of FIG. 11 along line L-L of FIG. 9, with additional structures that are not shown in FIG. 9 for simplicity. The top-down view of FIG. 9 can be along lines M-M of FIG. 11. The discussion of elements in FIGS. 1-11 with the same annotations applies to each other, unless mentioned otherwise. Referring to FIG. 11, in some embodiments, each of capacitor circuits 914A and 914B can include (i) trench capacitor 130*, instead of trench capacitor 130, (ii) metal via 126M5, (iii) metal line 128M6, and (iv) contact pad 132. The bottom horizontal portions of bottom conductive layers 130B* of trench capacitors 130* can be disposed in ESL 118M3 and can be disposed on and in contact with the top surface of power lines 928. In some embodiments, capacitor circuits 914A and 914B can be different from each other and not similar to each other as shown in FIGS. 10 and 11. In some embodiments, the cross-sectional view of FIG. 11 can have capacitor circuit 914A as shown in FIG. 10, instead of capacitor circuit 914A as shown in FIG. 11.

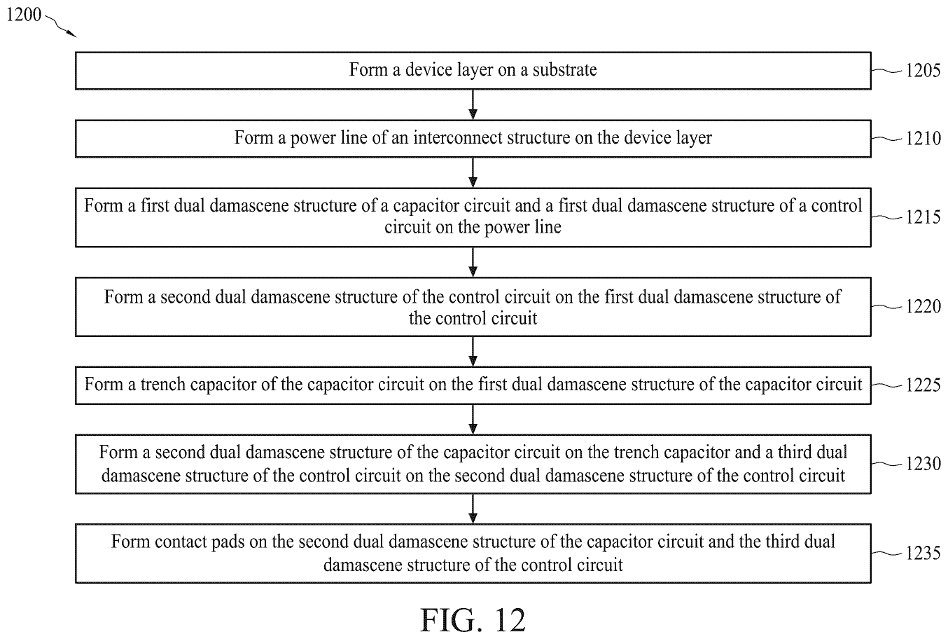

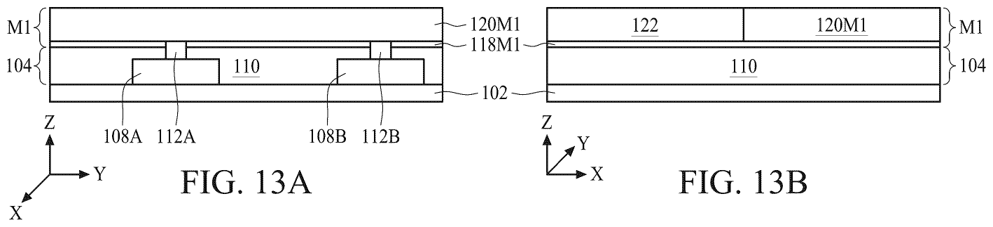

FIG. 12 is a flow diagram of an example method 1200 for fabricating IC 100 as shown in FIGS. 1-4, according to some embodiments. For illustrative purposes, the operations illustrated in FIG. 12 will be described with reference to the example fabrication process for fabricating IC 100 as illustrated in FIGS. 13A-24A and 13B-24B. FIGS. 13A-24A are cross-sectional views of IC 100 along line A-A of FIG. 1 at various stages of its fabrication, according to some embodiments. FIGS. 13B-24B are cross-sectional views of IC 100 along line C-C of FIG. 1 at various stages of its fabrication, according to some embodiments. Operations can be performed in a different order or not performed depending on specific applications. It should be noted that method 1200 may not produce a complete IC 100. Accordingly, it is understood that additional processes can be provided before, during, and after method 1200, and that some other processes may only be briefly described herein. The discussion of elements in FIGS. 1-4, 13A-24A and 13B-24B with the same annotations applies to each other, unless mentioned otherwise.

Referring to FIG. 12, in operation 1205, a device layer is formed on a substrate. For example, as described with reference to FIGS. 13A and 13B, device layer 104 having FETs 108A and 108B, ILD layer 110, and contact structures 112A and 112B are formed on substrate 102. FETs 108A and 108B and contact structures 112A and 112B are not visible in the cross-sectional view of FIG. 13B.

Referring to FIG. 12, in operation 1210, a power line of an interconnect structure is formed on the device layer. For example, as described with reference to FIGS. 13A and 13B, power line 122 of interconnect structure (shown in FIG. 2) is formed on device layer 104. Power line 122 is not visible in the cross-sectional view of FIG. 13A. In some embodiments, the formation of power line 122 can include sequential operations of (i) depositing ESL 118M1 on ILD layer 110, as shown in FIGS. 13A and 13B, (ii) depositing IMD layer 120M1 on ESL 118M1, as shown in FIGS. 13A and 13B, (iii) forming a trench (not shown) in IMD layer 120M1, (iv) depositing a metal layer (not shown) having the material of power line 122 in the trench, and (v) performing a chemical mechanical polishing (CMP) process on the metal layer to substantially coplanarize top surfaces of power line 122 and IMD layer 120M1, as shown in FIG. 13B.

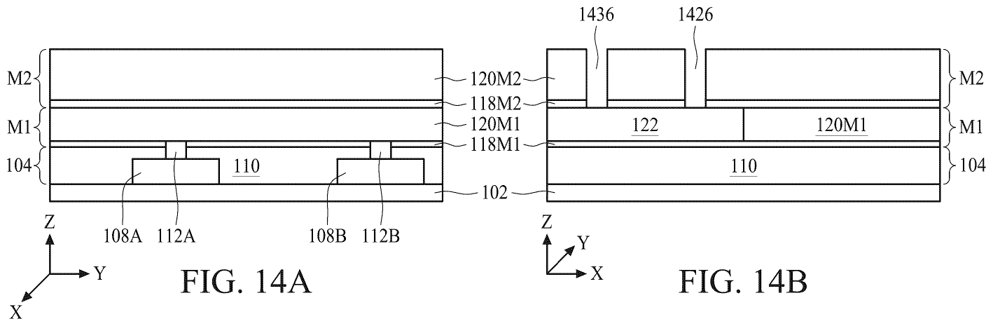

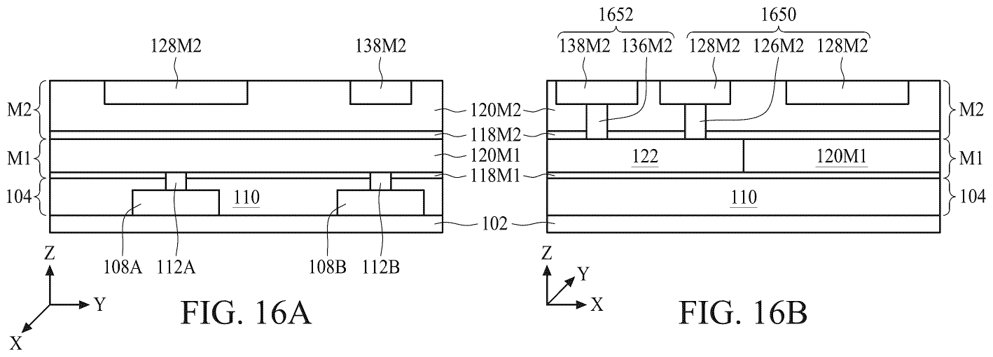

Referring to FIG. 12, in operation 1215, a first dual damascene structure of a capacitor circuit and a first dual damascene structure of a control circuit is formed on the power line. For example, as described with reference to FIGS. 14A-16A and 14B-16B, a first dual damascene structure 1650 of capacitor circuit 114B (shown in FIG. 2) having metal via 126M2 and metal line 128M2 and a first dual damascene structure 1652 of control circuit 116B (shown in FIG. 2) having metal via 136M2 and metal line 138M2 are formed on power line 122. Metal vias 126M2 and 136M2 of first dual damascene structures 1250 and 1252 are not visible in the cross-sectional view of FIG. 16A. In some embodiments, first dual damascene structures 1250 and 1252 can be formed in a via-first dual damascene process at the same time.

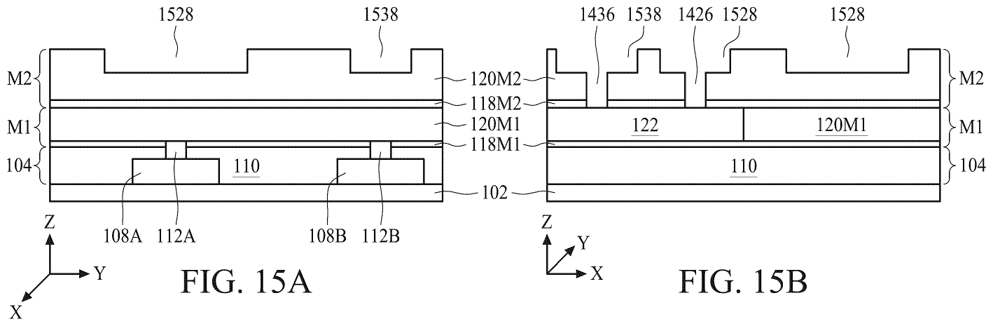

In some embodiments, the formation of first dual damascene structures 1250 and 1252 can include sequential operations of (i) depositing ESL 118M2 on the structures of FIGS. 13A and 13B, as shown in FIGS. 14A and 14B, (ii) depositing IMD layer 120M2 on ESL 118M2, as shown in FIGS. 14A and 14B, (iii) etching portions of IMD layer 120M2 and ESL 118M2 to form via openings 1426 and 1436 on power line 122 and expose a top surface of power line 122 through via openings 1426 and 1436, as shown in FIG. 14B (via openings 1426 and 1436 are not visible in the cross-sectional view of FIG. 14A), (iv) etching IMD layer 120M2 to form trenches 1528 and 1538, which are wider than via openings 1426 and 1436 along X- and Y-axes, as shown in FIGS. 15A and 15B, (v) depositing a metal layer (not shown) having the material of metal vias 126M2 and 136M2 and metal lines 128M2 and 138M2 to fill via openings 1426 and 1436 and trenches 1528 and 1538, and (vi) performing a CMP process on the metal layer to substantially coplanarize top surfaces of IMD layer 120M2 and metal lines 128M2 and 138M2, as shown in FIGS. 16A and 16B.

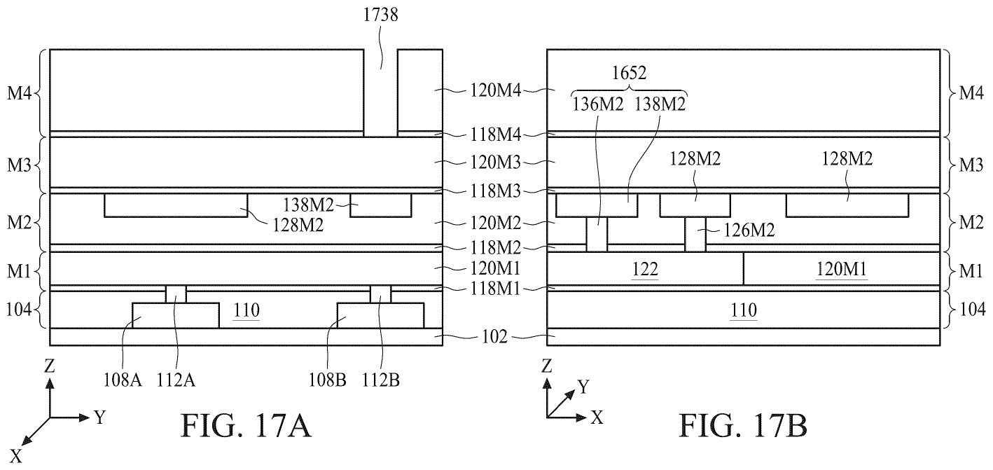

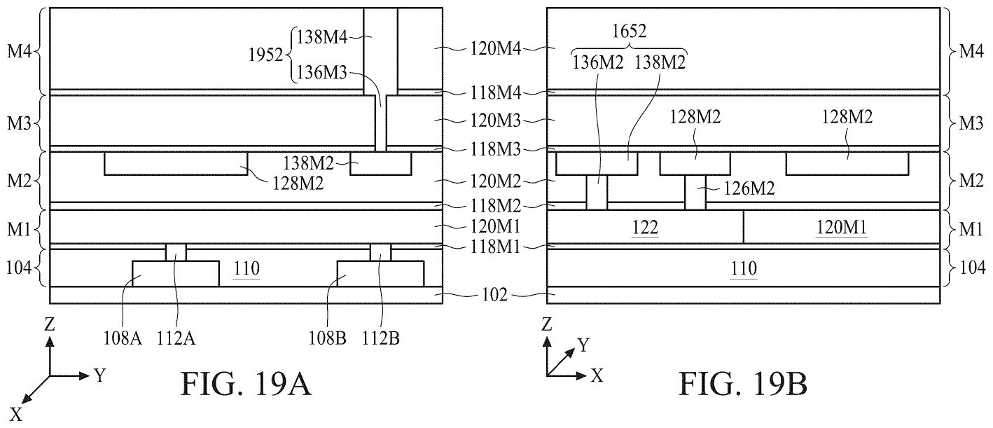

Referring to FIG. 12, in operation 1220, a second dual damascene structure of the control circuit is formed on the first dual damascene structure of the control circuit. For example, as described with reference to FIGS. 17A-19A and 17B-19B, a second dual damascene structure 1952 of control circuit 116B (shown in FIG. 2) having metal via 136M3 and metal line 138M4 is formed on first dual damascene structure 1652. Second dual damascene structure 1952 is not visible in the cross-sectional view of FIG. 19B. In some embodiments, second dual damascene structure 1952 can be formed in a trench-first dual damascene process, which is a different dual damascene process than that used in the formation of first dual damascene structures 1250 and 1252.

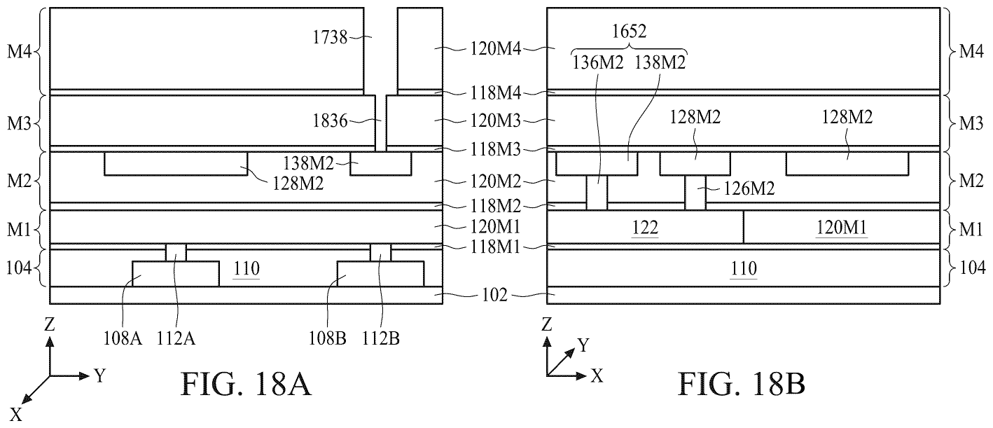

In some embodiments, the formation of second dual damascene structure 1952 can include sequential operations of (i) depositing ESL 118M3 on the structures of FIGS. 16A and 16B, as shown in FIGS. 17A and 17B, (ii) depositing IMD layer 120M3 on ESL 118M3, as shown in FIGS. 17A and 17B, (iii) depositing ESL 118M4 on IMD layer 120M3, as shown in FIGS. 17A and 17B, (iv) depositing IMD layer 120M4 on ESL 118M4, as shown in FIGS. 17A and 17B, (v) etching portions of IMD layer 120M4 and ESL 118M4 to form a trench 1738 on IMD layer 120M3 and expose a top surface of IMD layer 120M3 through trench 1738, as shown in FIG. 17A (trench 1738 not visible in the cross-sectional view of FIG. 17B), (vi) etching portions of IMD layer 120M3 and ESL 118M3 to form a via opening 1836 narrower than trench 1738 along a Y-axis on metal line 138M2 and expose a top surface of metal line 138M2 through via opening 1836, as shown in FIG. 18A (via opening 1836 not visible in the cross-sectional view of FIG. 18B), (vii) depositing a metal layer (not shown) having the material of metal via 136M3 and metal line 138M4 to fill via opening 1836 and trench 1738, and (viii) performing a CMP process on the metal layer to substantially coplanarize top surfaces of IMD layer 120M4 and metal line 138M4, as shown in FIG. 19A.

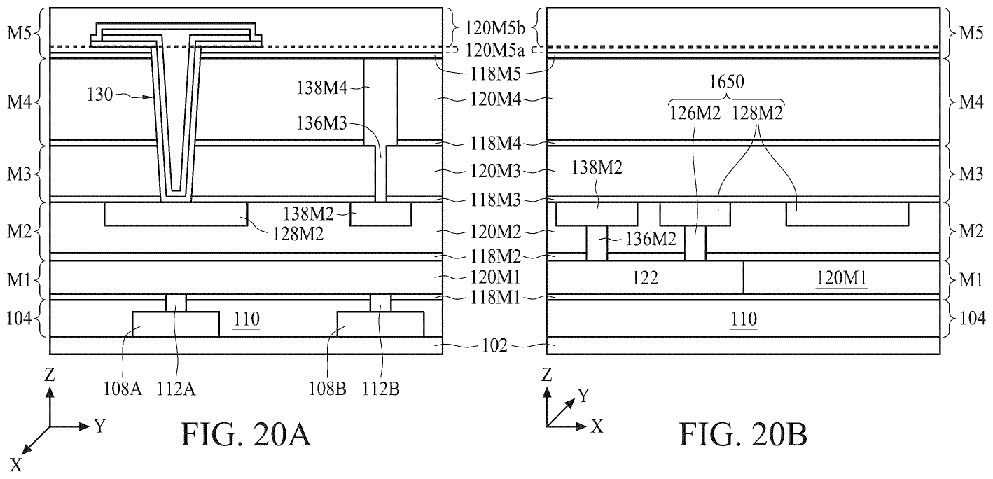

Referring to FIG. 12, in operation 1225, a trench capacitor of the capacitor circuit is formed on the first dual damascene structure of the capacitor circuit. For example, as described with reference to FIGS. 20A and 20B, trench capacitor 130 of capacitor circuit 114B (shown in FIG. 2) is formed on first dual damascene structure 1650. Metal via 126M2 of first dual damascene structure 1250 is not visible in the cross-sectional view of FIG. 20A and trench capacitor 130 is not visible in the cross-sectional view of FIG. 20B. In some embodiments, the formation of trench capacitor 130 can include sequential operations of (i) depositing ESL 118M5 on the structures of FIGS. 19A and 19B, as shown in FIGS. 20A and 20B, (ii) depositing a portion 120M5a of IMD layer 120M5 on ESL 118M5, as shown in FIGS. 20A and 20B, (iii) forming trench capacitor in ESL 118M3, IMD layer 120M3, ESL 118M4, IMD layer 120M4, and ESL 118M5, and on portion 120M5a of IMD layer 120M5, as shown in FIG. 20A, and (iv) depositing another portion 120M5b of IMD layer 120M5 on trench capacitor 130 to form the structures of FIGS. 20A and 20B.

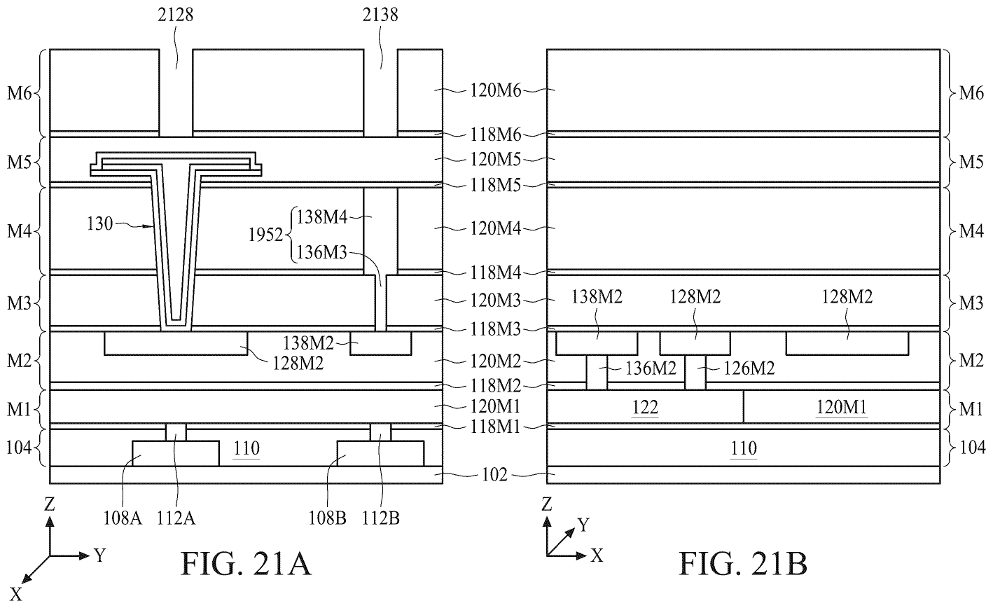

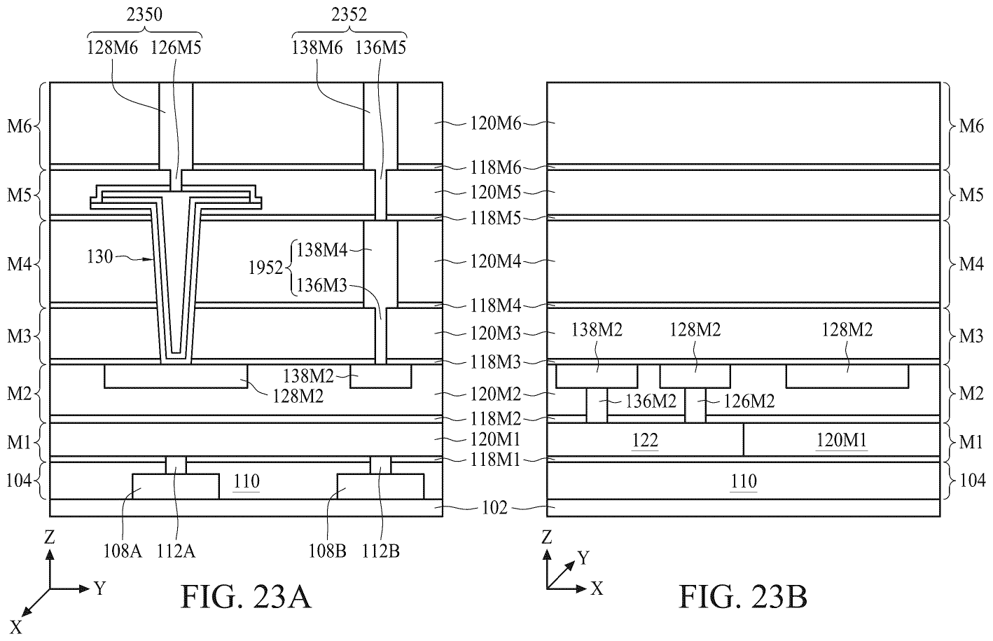

Referring to FIG. 12, in operation 1230, a second dual damascene structure of the capacitor circuit is formed on the trench capacitor and a third dual damascene structure of the control circuit is formed on the second dual damascene structure of the control circuit. For example, as described with reference to FIGS. 21A-23A and 21B-23B, a second dual damascene structure 2350 of capacitor circuit 114B (shown in FIG. 2) having metal via 126M5 and metal line 128M6 is formed on trench capacitor 130 and a third dual damascene structure 2352 of control circuit 116B (shown in FIG. 2) having metal via 136M5 and metal line 138M6 is formed on second dual damascene structure 1952. Second dual damascene structure 2350 and third dual damascene structure 2352 are not visible in the cross-sectional view of FIG. 23B. In some embodiments, second dual damascene structure 2350 and third dual damascene structure 2352 can be formed in a trench-first dual damascene process at the same time.

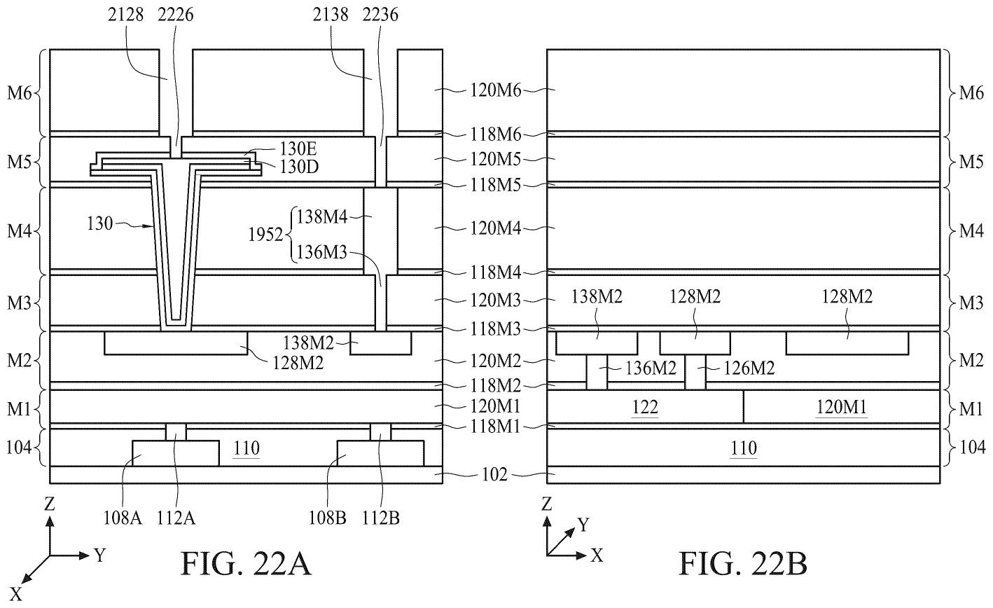

In some embodiments, the formation of second dual damascene structure 2350 and third dual damascene structure 2352 can include sequential operations of (i) depositing ESL 118M6 on the structures of FIGS. 20A and 20B, as shown in FIGS. 21A and 21B, (ii) depositing IMD layer 120M6 on ESL 118M6, as shown in FIGS. 21A and 21B, (iii) etching portions of IMD layer 120M6 and ESL 118M6 to form trenches 2128 and 2138 on IMD layer 120M5 and expose a top surface of IMD layer 120M5 through trenches 2128 and 2138, as shown in FIG. 21A (trenches 2128 and 2138 not visible in the cross-sectional view of FIG. 21B), (iv) etching portions of IMD layer 120M3, ESL 118M3, and capping layer 130E to form via openings 2226 and 2236, which are narrower than trenches 2128 and 2138 along a Y-axis and expose top surfaces of top conductive layer 130D and metal line 138M4 through via openings 2226 and 2236, as shown in FIG. 22A (via openings 2226 and 2236 not visible in the cross-sectional view of FIG. 22B), (v) depositing a metal layer (not shown) having the material of metal vias 126M5 and 136M5 and metal lines 128M6 and 138M6 to fill via openings 2226 and 2236 and trenches 2128 and 2138, and (vi) performing a CMP process on the metal layer to substantially coplanarize top surfaces of IMD layer 120M6 and metal lines 128M6 and 138M6, as shown in FIG. 23A.

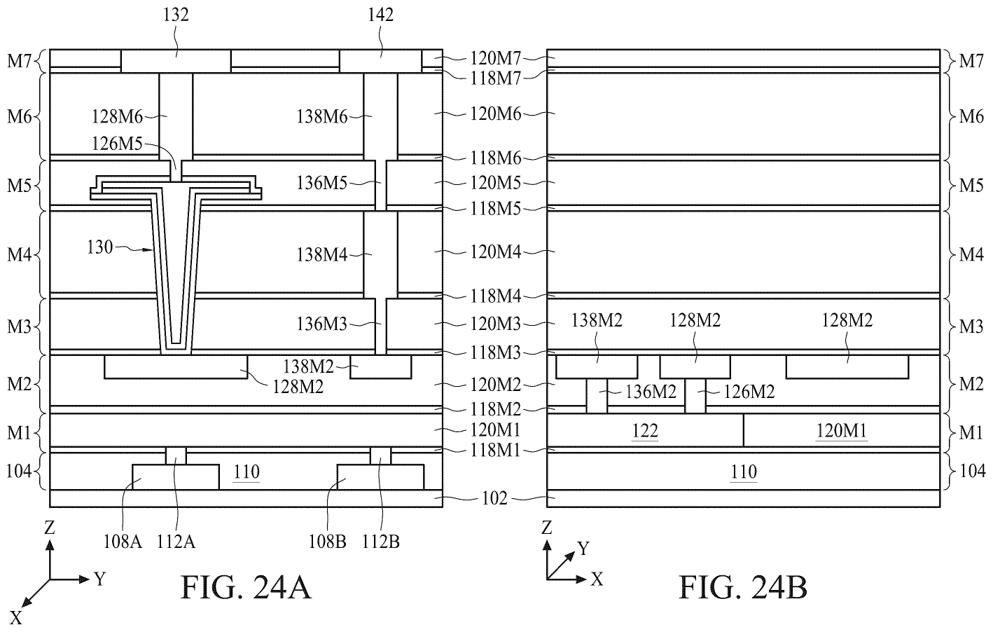

Referring to FIG. 12, in operation 1235, contact pads are formed on the second dual damascene structure of the capacitor circuit and the third dual damascene structure of the control circuit. For example, as described with reference to FIGS. 24A and 24B, contact pads 132 and 142 are formed on second dual damascene structure 2350 and third dual damascene structure 2352 at the same time. Contact pads 132 and 142 are not visible in the cross-sectional view of FIG. 24B. In some embodiments, the formation of contact pads 132 and 142 can include sequential operations of (i) depositing ESL 118M7 on the structures of FIGS. 23A and 23B, as shown in FIGS. 24A and 24B, (ii) depositing IMD layer 120M7 on ESL 118M7, as shown in FIGS. 24A and 24B, (iii) forming pad openings (not shown) in IMD layer 120M7, (iv) depositing a metal layer (not shown) having the material of contact pads 132 and 142 in the trenches, and (v) performing a CMP process on the metal layer to substantially coplanarize top surfaces of IMD layer 120M7 and contact pads 132 and 142, as shown in FIG. 24A.

The present disclosure provides example ICs (e.g., ICs 100, 600, 700, 800, and 900) with trench capacitor arrays (e.g., trench capacitors 130 and 130*) in interconnect structures (e.g., interconnect structures 106 and 906) having improved features, such as: (i) smaller trench capacitor unit cells, (ii) increased density of trench capacitors per unit area of the ICs, (iii) flexible metal line routing between power lines and trench capacitors, and (iv) reduced resistance-capacitance (RC) delay in the ICs. The present disclosure also provides example methods (e.g., method 1200) of forming the example interconnect structures. In some embodiments, these improved features can be achieved by reducing the number of power lines (e.g., power lines 122, 124, 822, and 824) in each trench capacitor unit cell (e.g., unit cell 100, 600, 700, 800, and 900) and/or by increasing the width of the power lines (e.g., about 40 nm to about 80 μm). Reducing the number of power lines can reduce the size of the trench capacitor unit cells, while increasing the width of the power lines can increase the density of trench capacitors (e.g., trench capacitors 130 and 130*) per unit area. With the use of wider power lines, the number of trench capacitors electrically connected to each power line can be increased because the wider power lines can provide increased flexibility in connecting the trench capacitors to the power lines. Due to the increased routing flexibility, in some embodiments, each power line can be electrically connected to two columns of trench capacitors, instead of only one column of trench capacitors. Also, due to the increased routing flexibility, the trench capacitors can be electrically connected to non-adjacent and adjacent control circuits (e.g., control circuits 116A-116L) by using longer metal lines (e.g., about 100 nm to about 1 μm long metal lines) and/or L-shaped metal lines (e.g., metal lines 128M2 and 138M2).

In some embodiments, a structure includes a substrate, a device layer disposed on the substrate, a power line disposed on the device layer, a first capacitor circuit, a second capacitor circuit, and a control circuit disposed on the power line and configured to control the first capacitor circuit. The first capacitor circuit includes a first conductive via disposed on the power line, a first conductive line disposed on the first conductive via and aligned to a first side of the power line, and a first trench capacitor disposed on the first conductive line. The second capacitor circuit includes a second conductive via disposed on the power line, a second conductive line disposed on the second conductive via and aligned to a second side of the power line, and a second trench capacitor disposed on the second conductive line.

In some embodiments, a structure includes a substrate, a voltage supply line disposed on the substrate, first and second capacitor circuits having first and second trench capacitors, respectively, disposed on and in contact with voltage supply line, and a control circuit disposed between the first and second capacitor circuits and overlapping the voltage supply line.

In some embodiments, a method includes forming a transistor on a substrate, depositing a first dielectric layer on the transistor, forming, at a same time, a first dual damascene structure of a capacitor circuit and a first dual damascene structure of a control circuit in the first dielectric layer, depositing a stack of etch stop layers and dielectric layers on the first dual damascene structure of the capacitor circuit and the first dual damascene structure of the control circuit, forming a second dual damascene structure of the control circuit in the stack of etch stop layers and dielectric layers, and forming a trench capacitor of the capacitor circuit in the stack of etch stop layers and dielectric layers and adjacent to the second dual damascene structure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
a device layer disposed on the substrate;
a power line disposed on the device layer;
a first capacitor circuit, comprising:
a first conductive via disposed on the power line,
a first conductive line disposed on the first conductive via and aligned to a first side of the power line, and
a first trench capacitor disposed on the first conductive line;
a second capacitor circuit, comprising:
a second conductive via disposed on the power line,
a second conductive line disposed on the second conductive via and aligned to a second side of the power line, and
a second trench capacitor disposed on the second conductive line; and
a control circuit disposed on the power line and configured to control the first capacitor circuit.

2. The structure of claim 1, wherein the first conductive line comprises:
a body portion non-overlapping with the first conductive via; and
an arm portion extending out from the body portion and overlapping with the first conductive via.

3. The structure of claim 1, wherein the first conductive line comprises:
a body portion comprising a rectangular cross-sectional profile; and
an arm portion extending out from the body portion and comprising an L-shaped or an I-shaped cross-sectional profile.

4. The structure of claim 1, wherein a portion of the first conductive line with an L-shaped or an I-shaped cross-sectional profile comprises a length of about 100 nm to about 1 μm.

5. The structure of claim 1, wherein the first conductive line comprises:
a body portion non-overlapping with the power line; and
an arm portion overlapping with the power line.

6. The structure of claim 1, wherein the first capacitor circuit is disposed on the first side of the power line; and
wherein the control circuit is disposed on the second side of the power line.

7. The structure of claim 1, further comprising an other control circuit disposed adjacent to the second capacitor circuit and configured to control the second capacitor circuit.

8. The structure of claim 1, further comprising a stack of first, second, and third dielectric layers disposed on the first conductive line, wherein the first trench capacitor extends through the stack of first, second, and third dielectric layers.

9. The structure of claim 1, further comprising a dielectric layer disposed on the first conductive line, wherein:
the first trench capacitor is disposed in the dielectric layer, and
the control circuit comprises a metal via disposed in the dielectric layer and adjacent to the first trench capacitor.

10. The structure of claim 1, wherein the control circuit comprises:
a first metal via disposed on the power line;
a first metal line disposed on the first metal via and adjacent to the first conductive line;
a second metal via disposed on the first metal line; and
a second metal line disposed on the second metal via, wherein the second metal via and the second metal are disposed adjacent to the first trench capacitor.

11. The structure of claim 1, wherein the first conductive line comprises a body portion with an elongated side that is perpendicular to an elongated side of the power line.

12. The structure of claim 1, wherein the control circuit is electrically connected to the first and second trench capacitors through the power line.

13. A structure, comprising:
a substrate;
a voltage supply line disposed on the substrate;
first and second capacitor circuits comprising first and second trench capacitors, respectively, disposed on and in contact with the voltage supply line; and
a control circuit disposed between the first and second capacitor circuits and overlapping the voltage supply line.

14. The structure of claim 13, wherein the control circuit comprises a metal via, and
wherein a top surface of the voltage supply line is in contact with bottom surfaces of the metal via and the first and second trench capacitors.

15. The structure of claim 13, further comprising a stack of first, second, and third dielectric layers disposed on the voltage supply line, wherein the first and second trench capacitors extend through the stack of first, second, and third dielectric layers.

16. The structure of claim 13, further comprising:
an etch stop layer disposed on the voltage supply line; and
a dielectric layer disposed on the etch stop layer,
wherein each of the first and second trench capacitors comprises:
a bottom conductive layer disposed in the etch stop layer and the dielectric layer,
a high-k dielectric layer disposed on the bottom conductive layer,
a top conductive layer disposed on the high-k dielectric layer, and
a capping layer disposed on the top conductive layer and in the dielectric layer.

17. The structure of claim 13, wherein the control circuit comprises a metal via and a metal line disposed between the first and second trench capacitors.

18. A method, comprising:
forming a transistor on a substrate;
depositing a first dielectric layer on the transistor;
forming, at a same time, a first dual damascene structure of a capacitor circuit and a first dual damascene structure of a control circuit in the first dielectric layer;
depositing a stack of etch stop layers and dielectric layers on the first dual damascene structure of the capacitor circuit and the first dual damascene structure of the control circuit;
forming a second dual damascene structure of the control circuit in the stack of etch stop layers and dielectric layers; and
forming a trench capacitor of the capacitor circuit in the stack of etch stop layers and dielectric layers and adjacent to the second dual damascene structure.

19. The method of claim 18, wherein the forming the first dual damascene structure of the capacitor circuit and the first dual damascene structure of the control circuit comprises performing a via-first dual damascene process on the first dielectric layer.

20. The method of claim 18, wherein the forming the second dual damascene structure comprises performing a trench-first dual damascene process on the stack of etch stop layers and dielectric layers.
